(19) United States
(12) Patent Application Publication
(10) Pub. No.: US 2019/0187957 A1
(43) Pub. Date: Jun. 20, 2019

(54) COMPACT BIT GENERATOR

(71) Applicant: Bar-Ilan University, Ramat-Gan (IL)

(72) Inventors: Moshe Avital, Moshav Manot (IL); Anatoli Mordakhay, Hadera (IL); Yoav Weizman, Kfar-Vitkin (IL); Osnat Keren, Rosh HaAyin (IL); Alexander Fish, Tel-Mond (IL)

(73) Assignee: Bar-Ilan University, Ramat-Gan (IL)

(21) Appl. No.: 16/224,869

(22) Filed: Dec. 19, 2018

Related U.S. Application Data
(60) Provisional application No. 62/607,393, filed on Dec. 19, 2017.

(51) Int. Cl. G06F 7/58; H03K 3/84; H03K 3/03

(52) U.S. Cl. CPC G06F 7/588; H03K 3/0315; H03K 3/84

(57) ABSTRACT

A bit generator includes a sampler and a voltage controlled oscillator (VCO) powered by a supply voltage. The sampler outputs a non-deterministic bit series which is generated by sampling an output of the VCO. The randomness of the non-deterministic bit series depends on inherent background noise and/or inherent clock jitter. Optionally, the bit generator does not include noise source circuitry.

### RELATED APPLICATION

This application claims the benefit of priority under 35 USC § 119(e) of U.S. Provisional Patent Application No. 62/607,393 filed on Dec. 19, 2017. The contents of the above application are all incorporated by reference as if fully set forth herein in its entirety.

### FIELD AND BACKGROUND OF THE INVENTION

The present invention, in some embodiments thereof, relates to a compact bit generator and, more particularly, but not exclusively, to a compact bit generator in a logic circuit.

There are many powerful circuit/gate level countermeasures against power analysis attacks that utilize randomization, for example, Randomized Multi-Topology Logic (RMTL), Blurring Gates, randomized power consumption based techniques and others. All require numerous random signals to randomize the power profile and/or the propagation delays of the logic paths. In most cases, a single True Random Number Generator (TRNG) provides the random signals for the required blocks. This kind of implementation has several disadvantages: the implementation cost of a TRNG is high, it consumes high energy since it always works, and even more importantly, a fault injection attack can neutralize it by forcing its output signal to be deterministic.

Existing hardware TRNGs employ a noise source that generates a random signal whose randomness is amplified. There are two types of TRNGs: those whose random output is sampled with the (deterministic) system clock and those that generate an output sequence with a jittered clock.

In general, TRNGs of the first type consist of a noise source, an amplifier, a sampler and other analog blocks. TRNGs of the second type involve a ring-oscillator at the data line, sampled by a noisy (jittered) clock resulting from an amplified noise source and additional analog blocks. The quality of the noise source determines the quality of the TRNG.

These noise based TRNGs have a complex structure since the noise source needs to be generated and amplified. In addition they include custom designed additional analog blocks (e.g., A/D, Sample&Hold module, Current-Controlled Oscillator, filters, etc.) to achieve true randomness. There are other techniques to implement random generators without the need of noise sources, such as metastability based TRNGs. However, similarly to the noise-source based TRNGs, they occupy a large area overhead.

Additional background art includes:
[1] M. Avital, H. Dagan, O. Keren, and A. Fish, “Randomized Multitopology Logic Against Differential Power Analysis,” IEEE Trans. Very Large Scale Integr. VLSI Syst., vol. PP, no. 99, pp. 1-1, 2014.
[2] M. Avital, I. Levi, O. Keren, and A. Fish, “CMOS Based Gates for Blurring Power Information,” IEEE Trans. Circuits Syst. Regul. Pap., vol. 63, no. 7, July 2016.
[3] M. Bucci, M. Guglielmo, R. Luzzi, and A. Trifiletti, “A Power Consumption Randomization Countermeasure for DPA-Resistant Cryptographic Processors,” in Integrated Circuit and System Design. Power and Timing Modeling, Optimization and Simulation, E. Macii, V. Paliouras, and O. Koufopavlou, Eds. Springer Berlin Heidelberg, 2004, pp. 481-490.
[4] M. Bucci, R. Luzzi, M. Guglielmo, and A. Trifiletti, “A countermeasure against differential power analysis based on random delay insertion,” in IEEE International Symposium on Circuits and Systems, 2005. ISCAS 2005, 2005, p. 3547-3550 Vol. 4.
[5] T. Popp and S. Mangard, “Masked Dual-Rail Pre-charge Logic: DPA-Resistance Without Routing Constraints,” in Cryptographic Hardware and Embedded Systems—CHES 2005, J. R. Rao and B. Sunar, Eds. Springer Berlin Heidelberg, 2005, pp. 172-186.
[6] T. Popp, M. Kirschbaum, T. Zefferer, and S. Mangard, “Evaluation of the Masked Logic Style MDPL on a Prototype Chip,” in Cryptographic Hardware and Embedded Systems—CHES 2007, P. Paillier and I. Verbauwhede, Eds. Springer Berlin Heidelberg, 2007, pp. 81-94.
[7] E. Alon, V. Stojanovic, and M. A. Horowitz, “Circuits and techniques for high-resolution measurement of on-chip power supply noise,” IEEE J. Solid-State Circuits, vol. 40, no. 4, pp. 820-828, April 2005.
[8] E. Alon, V. Abramzon, B. Nezamfar, and M. Horowitz, “On-Die Power Supply Noise Measurement Techniques,” IEEE Trans. Adv. Packag., vol. 32, no. 2, pp. 248-259, May 2009.
[9] E. Alon, “Measurement and regulation of on-chip power supply noise,” Ph.D. dissertation, Stanford University, Stanford, Calif., 2006.
[10] M. Bucci and R. Luzzi, “A Fully-Digital Chaos-Based Random Bit Generator,” in The New Codebreakers, P. Y. A. Ryan, D. Naccache, and J.-J. Quisquater, Eds. Springer Berlin Heidelberg, 2016, pp. 396-414.
[11] C. S. Petrie and J. A. Connelly, “A noise-based IC random number generator for applications in cryptography,” IEEE Trans. Circuits Syst. Fundam. Theory Appl., vol. 47, no. 5, pp. 615-621, May 2000.
[12] V. Bagini and M. Bucci, “A Design of Reliable True Random Number Generator for Cryptographic Applications,” in Cryptographic Hardware and Embedded Systems, Ç. K. Koç and C. Paar, Eds. Springer Berlin Heidelberg, 1999, pp. 204-218.
[13] M. Bucci, L. Germani, R. Luzzi, A. Trifiletti, and M. Varanonuovo, “A high-speed oscillator-based truly random number source for cryptographic applications on a smart card IC,” IEEE Trans. Comput., vol. 52, no. 4, pp. 403-409, April 2003.
[14] S. Robson, B. Leung, and G. Gong, “Truly Random Number Generator Based on a Ring Oscillator Utilizing Last Passage Time,” IEEE Trans. Circuits Syst. II Express Briefs, vol. 61, no. 12, pp. 937-941, December 2014.
[15] S. K. Mathew et al., “2.4 Gbps, 7 mW All-Digital PVT-Variation Tolerant True Random Number Generator for 45 nm CMOS High-Performance Microprocessors,” IEEE J. Solid-State Circuits, vol. 47, no. 11, pp. 2807-2821, November 2012.
[16] C. Tokunaga, D. Blaauw, and T. Mudge, “True Random Number Generator With a Metastability-Based Quality Control,” IEEE J. Solid-State Circuits, vol. 43, no. 1, pp. 78-85, January 2008.
[17] R. Ginosar, “Metastability and Synchronizers: A Tutorial,” IEEE Des. Test Comput., vol. 28, no. 5, pp. 23-35, September 2011.
[18] L. E. Bassham III et al., “A Statistical Test Suite for Random and Pseudorandom Number Generators for Cryptographic Applications,” National Institute of Standards & Technology, Gaithersburg, Md., United States, 2010.
[19] F. P. Miller, A. F. Vandome, and J. McBrewster, Advanced Encryption Standard. Alpha Press, 2009.

### SUMMARY OF THE INVENTION

Embodiments of the invention present a compact bit generator (also denoted herein a bit generator). The compact bit generator (cBG) includes a voltage controlled oscillator (VCO) powered by a supply voltage. The VCO produces an analog oscillation signal which is then sampled to generate a non-deterministic bit series whose randomness depends on the inherent background noise (e.g. supply noise) and/or inherent clock jitter. Process variations may introduce differences between the respective bit series generated by different cBGs in the same circuit and from circuit to circuit, even when the cBGs themselves have an identical or highly similar layout.

Due to its compact size, multiple cBGs may be embedded within a logic circuit, thereby providing gate-level randomization which is an effective countermeasure against power analysis attacks. Optionally, cBGs are placed at different physical locations within a logic circuit, thereby producing different and uncorrelated bit sequences at the different circuit locations.

As used herein, the term “bit series” means one or more bits generated by sampling the bit generator output over time. The number of bits in the series (i.e. length of series) and/or timing at which the bit generator output is sampled may vary.

As used herein, the term “non-deterministic bit series” means a series of bits in which even when the initial bits in the series are known it is unknown what the next bit will be. Even if the bit generator produces the same initial bit series, the subsequent bit may be different at different times of operation.

As used herein the term “inherent background noise” means background noise which is not introduced deliberately (e.g. by dedicated circuitry and/or input from an external source).

As used herein the term “inherent clock jitter” means variations in the clock signal which are not introduced deliberately (e.g. by dedicated circuitry which affects the timing of the clock signal).

The cBG does not require a noise source in order to generate the non-deterministic bit series. The cBG amplifies the inherent (residual) noise in voltage supply which exists in any power source. Process variations may serve to amplify the differences between adjacent cBGs.

The cBG may therefore be implemented with a very small size and does not require the additional resources (such as power) which are required by noise source circuitry. Optionally, the cBG includes circuitry to introduce additional noise into the cBG (for example to amplify the effects of the supply noise).

As used herein the term “noise source” means circuit elements and/or electrical connections which are present in the circuit in order to generate a random signal.

Embodiments of the cBG present many benefits, particularly over existing TRNGs, including:
a) The cBG may be implemented with standard-flow tools and libraries (e.g. the standard CMOS library), whereas the existing TRNGs involve custom design-based modules which make the implementation much more complex.
b) Small area—the cBG is at least 133 times smaller than any existing hardware based TRNG. The cBG is also smaller than the digital chaotic-based technique presented in [10], which includes additional blocks (such as a custom ring-oscillator, entropy extractor, and post processing) to achieve partial or full entropy bit sequences.
c) No routing overhead—due to their compact size, cBGs may be embedded simply in an existing design at any desired location, rather than routing long wires from a TRNG module.
d) Tampering immunity—the compact size of the cBG and the ability to embed many cBGs in the logic circuit design make them hard to neutralize.

According to an aspect of some embodiments of the present invention there is provided a bit generator which includes a sampler and a voltage controlled oscillator (VCO) powered by a supply voltage. The sampler outputs a non-deterministic bit series which is generated by sampling an output of the VCO. The randomness of the non-deterministic bit series depends on inherent background noise and/or inherent clock jitter.

According to some embodiments of the invention, the bit generator does not include noise source circuitry configured to generate a random signal.

According to some embodiments of the invention, the bit generator includes an enable input adapted to input an enable signal for enabling and disabling the VCO.

According to some embodiments of the invention, an output of the bit generator is connected to an input of a digital element. According to further embodiments of the invention, the digital element is powered by the supply voltage.

According to some embodiments of the invention, the bit generator is embedded in a logic circuit.

According to some embodiments of the invention, a sampling rate of the sampler is smaller than an oscillation frequency of the VCO.

According to some embodiments of the invention, the VCO includes multiple logic gates interconnected so as to create an oscillator.

According to some embodiments of the invention, the VCO is a ring oscillator.

According to some embodiments of the invention, the VCO includes at least one standard digital cell.

According to some embodiments of the invention, the VCO includes inverters connected in a ring.

According to some embodiments of the invention, the VCO includes an exclusive OR (XOR) gate connected to an inverter in a ring. The inverter output is connected to an input of the XOR gate and to an input of the sampler.

According to some embodiments of the invention, the VCO includes a XOR gate and one input of the XOR gate is connected to an enable signal. Inputting a first logic level into the second input enables operation of the VCO and inputting a second logic level into the second input disables operation of the VCO.

According to some embodiments of the invention, the sampler is configured to sample the output of the VCO in accordance with a clock signal.

According to some embodiments of the invention, the sampler includes a Flip-Flop (FF) having a first input connected to an output of the VCO and a second input connected to the clock signal.

According to an aspect of some embodiments of the present invention there is provided a logic circuit which includes multiple bit generators and multiple logic gates. The bit generators output respective non-deterministic bit series, wherein a respective randomness of each of the non-deterministic bit series depends on at least one of: inherent background noise for the respective bit generator and inherent clock jitter for the respective bit generators. Each of the logic gates includes:
a random signal input which serves to input a non-deterministic bit series from a respective one of the bit generators; and
at least one logic input which serves to input respective logic signals, wherein the logic gate implements a respective logic operation on the non-deterministic bit series input from the respective one of the bit generators and the respective logic signals.

According to some embodiments of the invention, at least one of the bit generators does not include noise source circuitry configured to produce random electrical noise.

According to some embodiments of the invention, at least one of the bit generators includes a respective enable input adapted to input an enable signal for enabling and disabling the respective bit generator.

According to some embodiments of the invention, at least two of the bit generators output uncorrelated non-deterministic bit series.

According to some embodiments of the invention, at least two of the bit generators are powered by different supply voltages.

According to some embodiments of the invention, each of the bit generators includes:
a respective voltage controlled oscillator (VCO); and
a respective sampler associated with the VCO, configured to generate the respective non-deterministic bit series by sampling an output of the respective VCO.

According to some embodiments of the invention, for at least one of the bit generators, a sampling rate of the respective sampler is smaller than an oscillation frequency of the respective VCO.

According to some embodiments of the invention, for at least one of the bit generators, the respective VCO includes multiple logic gates interconnected so as to create an oscillator.

According to some embodiments of the invention, for at least one of the bit generators, the respective VCO includes a ring oscillator.

According to some embodiments of the invention, for at least one of the bit generators, the respective VCO includes an exclusive OR (XOR) gate connected to an inverter in a ring. The inverter output is connected to an input of the XOR gate and to an input of the sampler. A second input of the XOR gate is connected to an enable signal for enabling and disabling the VCO.

According to some embodiments of the invention, for at least one of the bit generators, the respective sampler samples the output of the VCO in accordance with a clock signal.

According to some embodiments of the invention, the respective sampler includes a Flip-Flop (FF) which has a first input connected to an output of the VCO and a second input connected to the clock signal.

According to some embodiments of the invention, at least one of the logic gates is a blurring gate.

According to an aspect of some embodiments of the present invention there is provided a logic unit which includes a logic gate and a voltage controlled oscillator (VCO) powered by a supply voltage and configured to output an analog oscillation signal.

The logic gate includes:
a sampler connected to an output of the VCO, which generates a non-deterministic bit series by sampling the analog oscillation signal, wherein a randomness of the non-deterministic bit series depends on at least one of: inherent background noise and inherent clock jitter;
at least one logic input for inputting respective logic signals;
a logic path for implementing a logic operation on the non-deterministic bit series and the respective logic signals; and
a logic output associated with the logic element, configured to output a result of the logic operation.

According to some embodiments of the invention, the logic unit does not include noise source circuitry configured to generate a random signal.

According to some embodiments of the invention, logic unit further includes an enable input adapted to input an enable signal for enabling and disabling the VCO.

According to some embodiments of the invention, a sampling rate of the sampler is smaller than an oscillation frequency of the VCO.

According to some embodiments of the invention, the VCO includes multiple logic gates interconnected so as to create an oscillator.

According to some embodiments of the invention, the VCO includes a ring oscillator.

According to some embodiments of the invention, the VCO includes at least one standard digital cell.

According to some embodiments of the invention, the VCO includes inverters connected in a ring.

According to some embodiments of the invention, the VCO includes an exclusive OR (XOR) gate connected to an inverter in a ring, and the inverter output is connected to an input of the XOR gate and to an input of the sampler.

According to some embodiments of the invention, the VCO includes a XOR gate and an input of the XOR gate is connected to an enable signal for enabling and disabling the VCO.

According to some embodiments of the invention, sampler samples the output of the VCO in accordance with a clock signal.

According to some embodiments of the invention, the sampler includes a Flip-Flop (FF) having a first input connected to an output of the VCO and a second input connected to the clock signal.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified block diagram of a compact bit generator, according to embodiments of the invention;

FIGS. 2A and 2B are simplified block diagrams of a logic unit, according to respective embodiments of the invention;

FIG. 3 is a simplified block diagram of a logic circuit according to embodiments of the invention;

FIG. 4 is a simplified block diagram of a logic circuit with embedded blurring gates;

FIG. 5 is a simplified block diagram of a compact bit generator, according to an exemplary embodiment of the invention;

FIG. 6 is a histogram of the percentage of ones in a simulated output sequences of an exemplary cBG cell;

FIG. 7 illustrates test setups for a single exemplary cBG cell and for an 8-bit S-box with embedded blurring gates and exemplary cBG cells.

### DESCRIPTION OF SPECIFIC EMBODIMENTS OF THE INVENTION

The present invention, in some embodiments thereof, relates to a compact bit generator and, more particularly, but not exclusively, to a compact bit generator in a logic circuit.

Embodiments of the cBG include a VCO followed by a sampler as described in more detail below. The randomness of the cBG output bit series output depends on the inherent background noise (which may originate in the power supply) and/or the inherent jitter of the sampler clock signal.

Optionally, the cBG does not include additional circuitry which serves to generate a random signal (e.g. a noise source). This is in contrast with TRNGs, which include dedicated noise source circuitry.

It is noted that even though the cBG does not include a noise source for the purpose of generating the bit series, a noise source may be present for other purposes in a circuit in which the cBG is embedded.

Optionally, the cBG does not include any element or circuitry adapted to neutralize the inherent noise in the power supply and/or the inherent jitter of the sampler clock signal.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Compact Bit Generator (cBG)

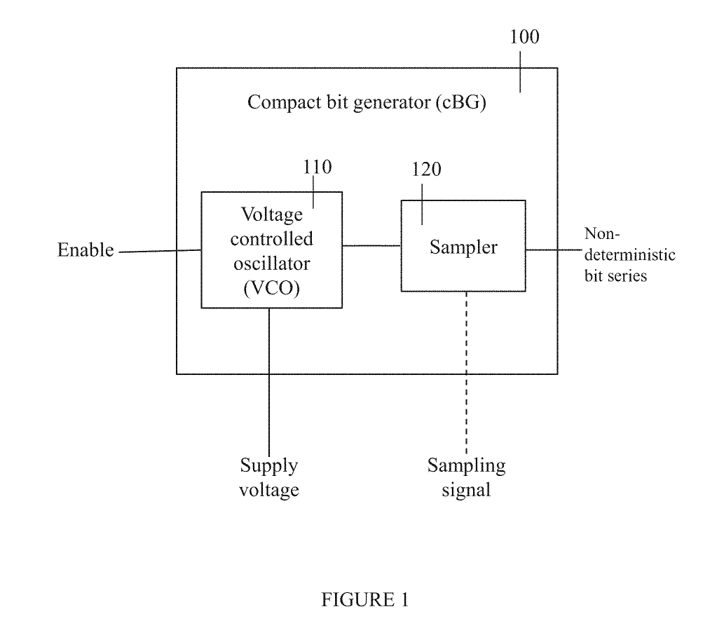

Referring now to the drawings, FIG. 1 is a simplified block diagram of a compact bit generator, according to embodiments of the invention.

cBG 100 includes VCO 110 followed by sampler 120. VCO 110 is powered by a supply voltage and outputs an analog oscillation signal. Sampler 120 samples the VCO output signal and outputs the resulting in a non-deterministic (e.g. random) bit series.

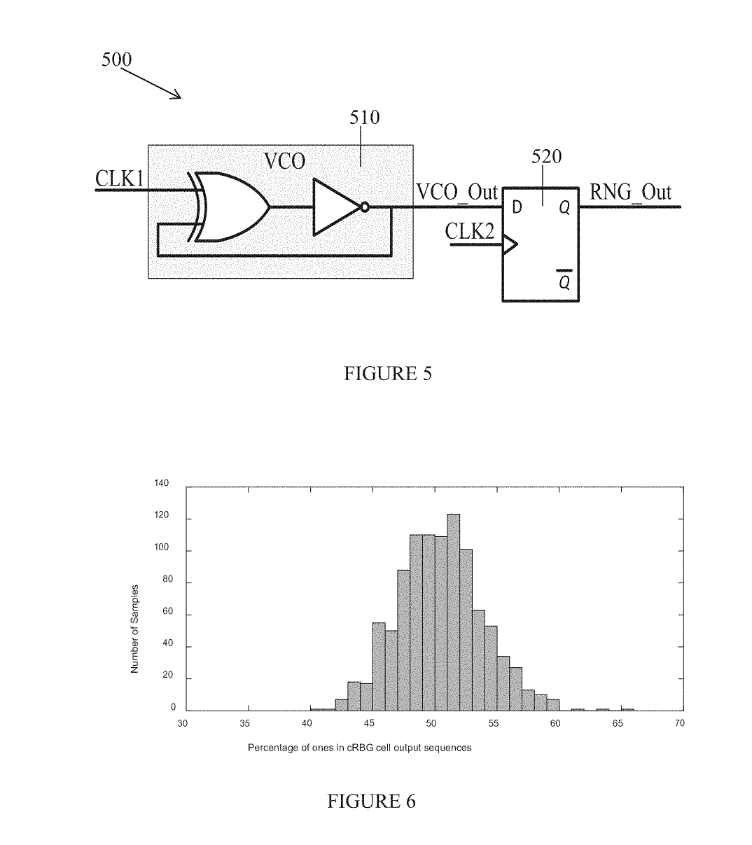

Optionally, cBG 100 further includes an enable input for inputting an enable signal which enables and disables VCO operation. When the VCO is disabled cBG 100 may consume less power than when the VCO is operating, thereby creating a power saving mode for cBG operation. For example, in the exemplary cBG illustrated in FIG. 5, the CLK1 input into the XOR may be used as an enable input. When CLK1=‘0’ the VCO is enabled and when CLK1=‘1’ the VCO is disabled and the VCO output is locked on a constant value.

### Voltage Controlled Oscillator

VCO 110 may be designed in any way known in the art including but not limited to:

i) Multiple logic gates interconnected to form an oscillator;

ii) A ring oscillator;

iii) Inverters connected in a ring; and

iv) An exclusive OR (XOR) gate connected to an inverter in a ring (see FIG. 5).

### Sampler

Optionally, sampler 120 samples the output of VCO 110 when triggered by a sampling signal.

Optionally sampler 120 samples the VCO output when triggered by a sampling signal.

Optionally, the sampling signal is a sampling clock signal with inherent clock jitter. Jitter (inherent and/or deliberately added) in the sampling clock signal may be one factor which introduces randomness into the sampled oscillation signal.

Optionally, the sampling signal is provided by an external circuit element. Alternately, sampler 120 includes an internal clock.

Optionally the sampler samples the VCO output at one or more of:

i) per cycle of the sampling clock signal;

ii) per multiple cycles of the sampling clock signal (e.g. once every three cycles);

iii) as required (i.e. at the time the next bit in the series is needed for circuit operation);

iv) at random intervals; and

v) in bursts of the same or different lengths.

Optionally, the sampling rate of the sampler is smaller than the oscillation frequency of the VCO. Typically, the sampling clock rate is a given parameter. Using high oscillation frequency increases the probability of sampling different digital values every sampling (clock) cycle. In one test case, the oscillation frequency was designed to be approximately 5 GHz for a sampling rate of approximately 100 MHz, yielding many high-frequency oscillation cycles in each low-frequency cycle. The randomness of the cBG output series depends on the background noise and process variations. As such it has been found to give satisfactory results when real power supply characteristics taken from laboratory experiments are utilized during simulations of the cBG (as demonstrated by the results presented below).

Further optionally, the oscillation frequency of the VCO is:

i) at least 5 times the sampling rate;

ii) at least 10 times the sampling rate.

Optionally, sampler 120 is a Flip-Flop (FF), with one input connected to the output of the VCO and a second input for the sampling clock signal.

Optionally, cBG 100 is a CMOS cell. However the cBG is not limited to CMOS implementations. Other technologies in which the cBG may be implemented include but are not limited to:

a) Pass Transistor Logic (PTL);

b) Differential PTL;

c) Pseudo-NMOS;

d) Pseudo-PMOS;

e) Dynamic Logic;

f) Differential Dynamic Logic;

g) Domino Logic; and

h) NP-CMOS.

Optionally, cBG 100 is designed from standard digital cells which are referenced in a standard cell library as known in the art.

Optionally, cBG 100 is designed using standard circuit design tools known in the art.

An exemplary embodiment of a cBG is described below and illustrated in FIG. 5. The exemplary cBG includes a VCO which is implemented as a XOR gate/inverter combination. The sampler is implemented as a D Flip-Flop. The VCO and D Flip-Flop have respective clock inputs, where the clock input into the VCO (CLK1) serves to lock the VCO circuit on a constant value.

### Randomized Logic Unit

Optionally, the non-deterministic bit series is used to introduce randomization into the operation of a logic gate.

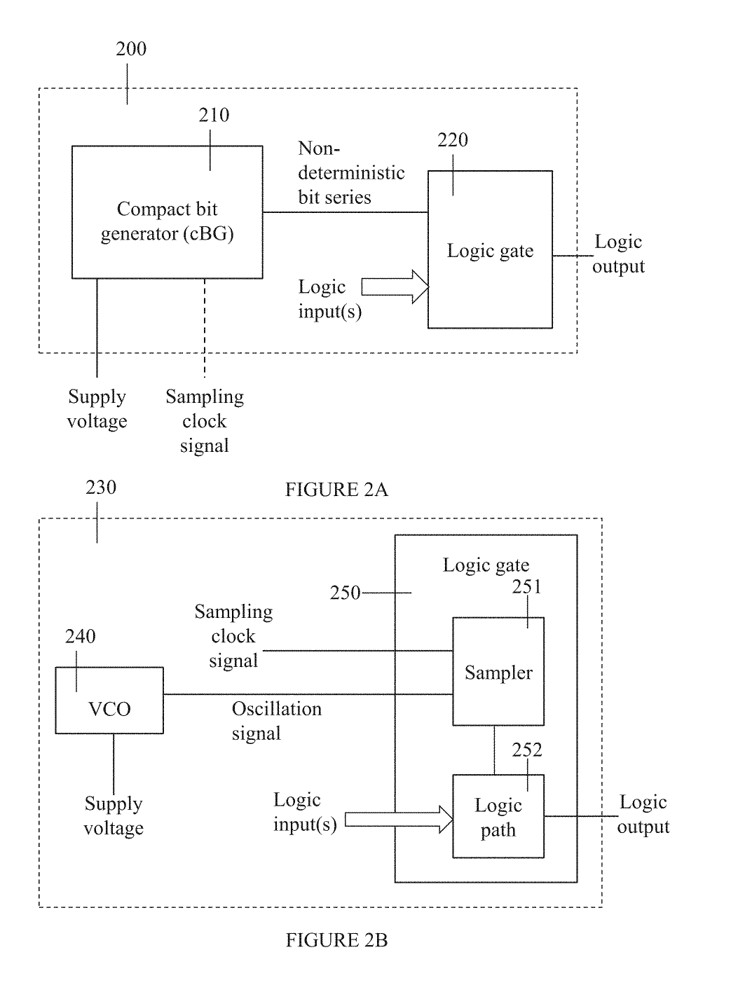

Reference is now made to FIGS. 2A and 2B, which are simplified block diagrams of a logic unit, according to respective embodiments of the invention.

In FIG. 2A, logic unit 200 includes cBG 210 which outputs a non-deterministic bit series. The non-deterministic bit series is input to logic gate 220. Logic gate 220 implements a logic function on the non-deterministic bit series from cBG 210 along with one or more input logic signals. In this way randomization is introduced into the output of logic gate 220 whose output depends not only on the deterministic logic signals at the logic inputs but also on the non-deterministic nature of the signal output by cBG 210.

cBG 210 includes a VCO followed by a sampler. The non-deterministic bit series output by cBG 210 is provided to an input of the logic gate. Examples of logic gates which may follow the cBG include but are not limited to:
a) Flip-Flop;
b) Latch;
c) NOT gate;
d) NAND gate;
e) AND gate;
f) NOR gate;
g) OR gate;
h) XOR gate;
i) XNOR gate;
j) MUX; and
k) Any other logic gate, provided that the connectivity does not harm the functionality of the cBG (for example due to metastability).

Optionally, cBG 210 may be switched off, so that logic gate 220 implements the logic function on the input logic signals without introducing randomization by cBG 210.

cBG 210 and/or logic gate 220 may be designed in any way known in the art, including but not limited to the embodiments presented herein.

In FIG. 2B, logic unit 230 includes VCO 240 and logic gate 250. In the embodiment of FIG. 2B, sampler 251 is part of logic gate 250 (as opposed to the embodiment of FIG. 2A in which the sampler is part of cBG 210). Logic gate 250 also includes logic path 252, whose output is a function of the non-deterministic bit signal output by sampler 251 and input logic signals.

Optionally, additional (i.e. non-inherent) noise is introduced into the sampling clock signal, thereby introducing additional randomization into the output of logic path 252.

VCO 240 and/or sampler 251 and/or logic path 252 may be designed in any way known in the art, including but not limited to the embodiments presented herein.

Optionally, the logic unit is designed with standard circuit design tools utilizing a standard cell library as known in the art.

Logic Circuit with Embedded cBGs

Due to the compact size attainable with embodiments of the cBG presented herein, multiple cBGs may be interspersed within a logic circuit design in order to add randomness to the power usage of the logic circuit thereby combating power analysis attacks.

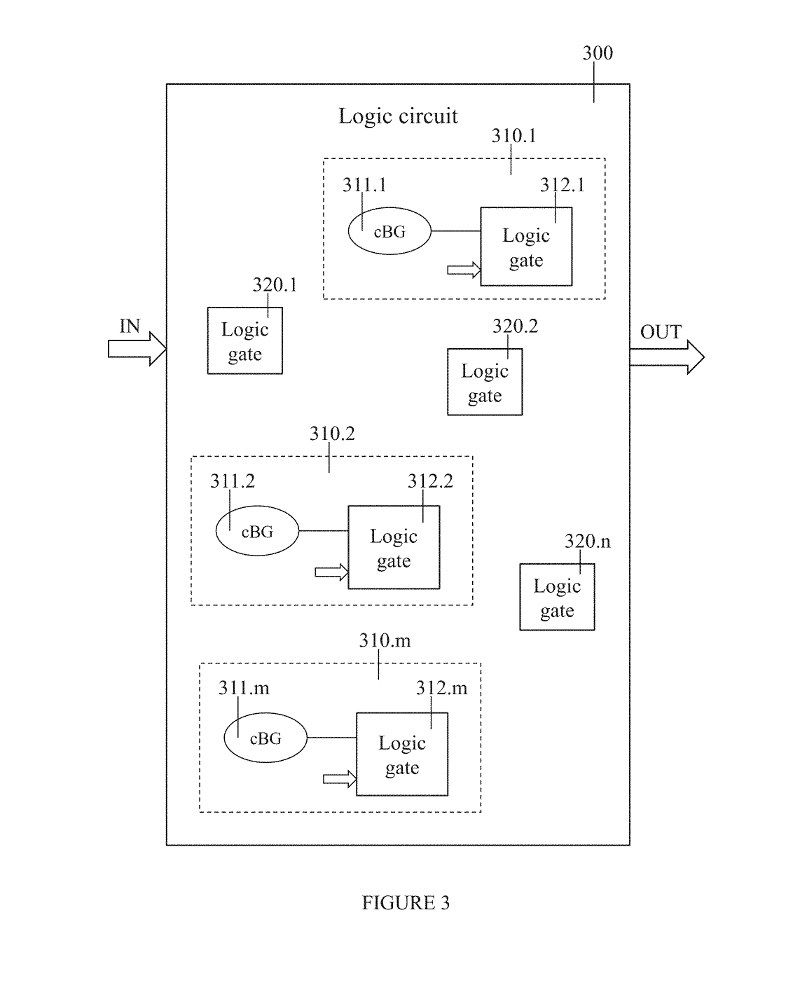

Reference is now made to FIG. 3, which is a simplified block diagram of a logic circuit according to embodiments of the invention. Logic circuit 300 includes multiple interconnected logic gates. At least some of the logic gates implement a logic function on one or more logic signals and a non-deterministic bit series from a respective cBG (similarly to the logic units illustrated in FIGS. 2A and 2B).

For purpose of illustration, FIG. 3 shows an exemplary logic circuit which includes logic units 310.1-310.m. Logic circuit 300 additionally includes logic gates 320.1-320.n which are not connected to a cBG. For clarity, the interconnections between the logic gates are not shown.

Although FIG. 3 shows an example in which each of logic units includes a respective cBG and logic gate, other embodiments are possible in which for at least one of the logic units the sampler is located within the logic gate (as described above for FIG. 2B).

Optionally, at least two of the cBGs are powered by different supply voltages.

Optionally, the circuit design is configured to reduce correlation between the non-deterministic bit series output by at least two of the cBGs. For example, the cBGs may be placed in different physical locations in the logic circuit, in proximity to different sources of background noise and/or with different length wires from the power supply. Other optional factors which may reduce correlation include but are not limited to:
i) Different supply voltages;
ii) Different or unknown wake-up state of the cBG;
iii) Different physical environment of the cBG cells (and hence different parasitic capacitances);
iv) Different oscillation frequencies of different cBG cells due to mismatch between the gates; and
v) Different clock signals.

It is noted that even when multiple cBGs are connected to the same clock signal the inherent clock jitter may differ amongst the multiple cBGs due differences, for example, in circuit layout and other design and manufacturing parameters.

Optionally, logic circuit 300 includes at least two differently designed cBGs (e.g. a first cBG with a VCO formed from a ring of inverters and a second cBG with a VCO formed from a XOR gate and inverter).

Optionally, at least one of the logic gates is a blurring gate.

Optionally, the logic circuit is designed with standard circuit design tools utilizing a standard cell library as known in the art.

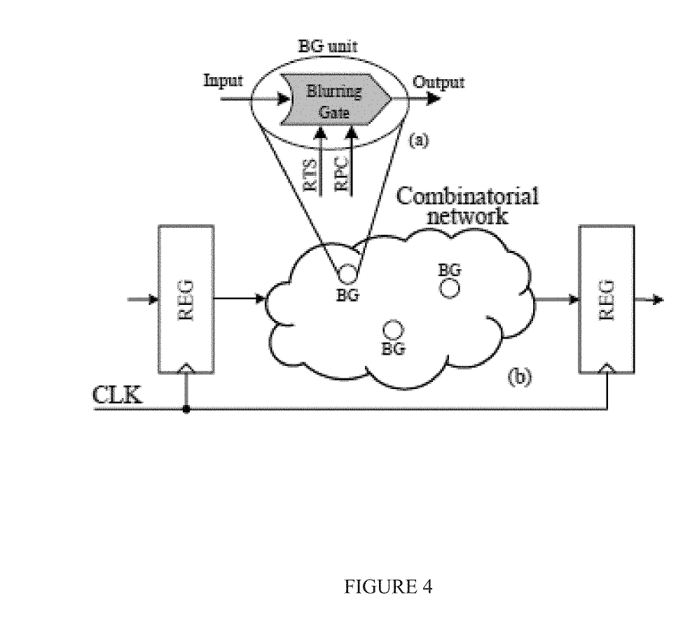

Reference is now made to FIG. 4, which is a simplified block diagram of a logic circuit with embedded blurring gates (also denoted BGs), in accordance with an exemplary embodiment of the invention. FIG. 4 shows an exemplary embodiment of a combinatorial network in which at least some of the logic gates are blurring gates. Multiple cBGs (not shown) provide respective non-deterministic bit series to the RPC inputs of the blurring gates.

The embodiment of FIG. 4 is used as a test case (described below) for the exemplary cBG shown in FIG. 5. In the test case described below, the combinatorial network is configured as an 8-bit CMOS S-box. Simulation results demonstrate the efficiency of the cBGs as a substitute for the unwieldy TRNG implementation. The simulation results clearly show that the use of cBGs as the RPC signals of the blurring gates kept the S-box immune to power analysis attacks.

Embodiments of the cBG, logic unit and/or logic circuit described herein may be implemented in circuits, including, but not limited to:

a) An integrated circuit (IC) customized for a particular use, such as an Application-Specific Integrated Circuit (ASIC);

b) A programmable logic device intended for general-purpose use. Examples of such programmable logic devices include, but are not limited to: Field-Programmable Gate Array (FPGA), Gate Array, Uncommitted Logic Array (ULA), Programmable Logic Array (PLA), Programmable Array Logic (PAL), Complex Programmable Logic Device (CPLD), Erasable Programmable Logic Device (EPLD) and Structured ASIC.

### Exemplary Embodiment of a cBG

### A. Structure of Exemplary cBG

Reference is now made to FIG. 5, which is a simplified block diagram of an exemplary cBG cell. cBG 500 (also referred to herein as “exemplary cBG” and “exemplary cBG cell”) includes a standard CMOS cell Voltage Controlled Oscillator (VCO) 510 and a D-Flip-Flop (DFF) 520. Both the inherent noise in the power supply and the jitter of the clock signals contribute to the randomness of the exemplary cBG.

When CLK1=‘0’, the XOR and the inverter in VCO 510 form a free running ring-oscillator circuit and the VCO_Out (high frequency) signal is impacted by the supply noise of these gates. DFF 520 samples the VCO_Out signal with a lower frequency than the VCO's CLK2. Note that larger supply noise bandwidth leads to increased randomness at the RNG_Out output. When CLK1=‘1’, VCO 510 is locked on a constant value.

The XOR gate may be used to save power when there is no need to generate a random sequence. If power dissipation is not a concern, the XOR gate may be replaced, for example, by two inverters.

Optionally, several exemplary cBG cells are embedded at different physical locations in a design and each cell operates from a supply voltage with different noise. Additionally, each of the exemplary cBG cells performs differently due to process variations. Thus different bit sequences are generated.

Reference is now made to FIG. 6, which shows simulation results for exemplary cBG cells. 1000 exemplary cBGs were tested using Monte Carlo simulations. Each exemplary cBG was tested under the same conditions:
A power supply of VDD=1.2V tampered with 10 mvᵣₘₛ white noise (characterized as in [7]).
CLK1 was set to ‘0’ in order to enable a free running VCO.
The DFF clock (CLK2) was set to 100 MHz.

FIG. 6 presents a histogram based on Monte Carlo simulations over 1,000 samples. The histogram shows the distribution of the bias as the percentage of ones in a sequence of length 10,000 output by exemplary cBG. The histogram indicates that on average the proportion of zeroes and ones at the output of the exemplary cBG is close to 50%. Nevertheless, due to process variations and supply noise, a sequence generated by a single exemplary cBG may be slightly biased. Nonetheless, sequences generated by physically adjacent exemplary cBG cells are different and uncorrelated.

It is noted that because of its structure, an exemplary cBG cell may reach metastability (in the case where CLK1=CLK2). However, this temporary phenomenon is not a concern because it is only necessary to have a distinct logic value right before the sampling time (rather than preventing the temporary metastable state). Since DFF 520 ensures that this occurs, no additional hardware components are needed. This is in contrast with other random number generators (e.g. TRNGs), which dedicate resources to preventing metastability (e.g. by adding a delay, flip-flop or inverter to the random generator design).

### B. Utilization of Exemplary cBG Cells

A blurring gate (BG) based implementation is used as a test case in order to demonstrate the performance of the exemplary cBG cell. BG units are standard cell-based logic gates which are implemented at different locations along the propagation paths of an existing design. BGs do not change the functionality of the system. Each BG may operate in a static CMOS-like mode or in one of two dynamic modes, pre-charge or pre-discharge. A BG may switch randomly between the two operational modes, thus producing a random initial condition at its output node and a random power profile for the device.

As illustrated in FIG. 4, a BG unit has two external control signals, the Random Transitions Sequence (RTS) and the Random Phase Control (RPC). The RTS signal is governed internally by an RTS block that provides different clock phases to each BG unit (or group of units). The RPC signal is governed externally by an existing TRNG module to achieve high immunity to power analysis.

As demonstrated herein, the expensive TRNG may be replaced by exemplary cBG cells without noticeable degradation in immunity to power attacks. In fact, due to process variations and the dependency of the noise and the RPC phases on the BG physical locations, it is possible to implement physically adjacent exemplary cBG cells with similar supply noise and still obtain different output sequences.

It is also noted that random sequences generated by two different (and even adjacent) exemplary cBG cells are not be correlated because all the logic including the (typically relatively small number of) cRBC cells are connected to the same voltage supply, thus the effect of each noise is negligible. Moreover, Monte Carlo simulations over 1,000 different exemplary cBGs with a pure (noiseless) supply voltage show that the standard deviation on the oscillation frequency is σ=150 MHz. The difference between the output sequences increases when the exemplary cBG cells are connected to different loads.

### C. Efficiency Criteria

Several statistical tests were used to characterize the effectiveness of the exemplary cBG cell for gate level randomization countermeasures to power analysis attacks. The BG-based implementation of [2] is referred to as a benchmark. The tests performed includes:

i) Template Matching—

The purpose of this test is to detect when there are too many occurrences of given aperiodic patterns. Template matching tests are important for high statistic averaging; when too many aperiodic patterns occur, an attacker may establish large statistics to construct the power profile from these patterns (these tests are equivalent to NIST tests #7, 8 [18]).

ii) Discrete Fourier Transform—

The purpose of this test is to detect periodic features (i.e., repetitive patterns that are near each other) in the tested sequence. This test is highly important since the attacker may use periodic features to choose when to attack, for example by synchronizing the attack to these periodic patterns (this test is equivalent to NIST test #6).

iii) Linear Complexity—

This test determines whether or not the sequence is complex enough to be considered random by examining the length of a linear feedback shift register (this test is equivalent to NIST tests #10).

iv) Frequency of m-Bit Patterns—

This test shows the frequency of all possible overlapping m-bit patterns over the entire sequence (this test is equivalent to NIST tests #11).

v) Random Excursions—

These tests determine the number of cycles having exactly K visits in a cumulative sum random walk, and the total number of times that a particular state occurs in a cumulative sum random walk (these tests are equivalent to NIST tests #14, 15).

The NIST test suite [18] includes additional tests which are not relevant in the context of the immunity to power analysis when several exemplary cBGs are implemented in the BG-based module. This is because the sequences generated by those exemplary cBGs are uncorrelated. In other words, in some of these tests embedding many (inherently) uncorrelated exemplary cBG cells compensates for the possible failure of one or some of those exemplary cBG cells.

### D. Test Setup

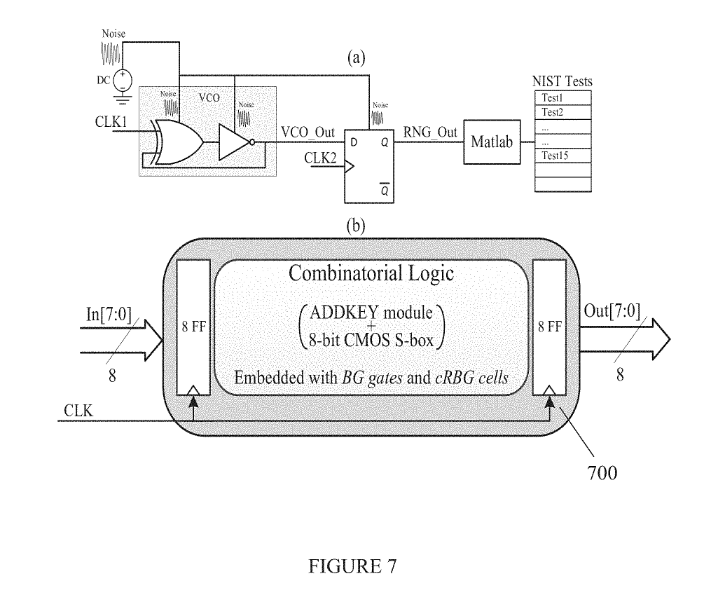

The testing was performed on an exemplary cBG circuit implemented in 65 nm standard CMOS technology with a 1.2V VDD, using a Cadence Virtuoso environment, with a 100 MHz clock. Two test setups were constructed, as shown in FIG. 7. The upper setup, labeled (a), is for a single exemplary cBG cell. The lower setup, labeled (b), is for a system level implementation using an 8-bit S-box with embedded BG gates and exemplary cBG cells. Both setups include noise added to the supply voltage.

Several noise types were examined, including white noise with a 10 GHz Bandwidth, white noise combined with dominant spurs at the system clock frequency multiples, and white noise combined with dominant spurs at different frequency multiples from the system clock frequency. The output sequences of the exemplary cBG cells (for the single cell test) and the power profile traces (for the system level test) were extracted by Virtuoso and processed using Matlab.

### E. Statistical Tests at the Cell Level

The characteristics of the (residual) noise in power supplies was studied in [7]-[9], and present a measurement system for characterization of power supply noise in advanced technologies. The supply noise measurement results of several chips showed that the spectrums of the noise contain white noise as well as dominant harmonics (spurs) of the system clock and its multiplications.

In order to resemble a real power supply, the exemplary cBGs were tested using simulated supply noise with characteristics similar to the ones reported in [7]-[9]. Several test cases were examined, as shown in Table I. Each test case corresponds to a different supply noise content: 20 mvᵣₘₛ white noise, 10 mvᵣₘₛ white noise, 10 mvᵣₘₛ white noise+spurs@k×100 MHz, k∈ [symbol] , and 10 mvᵣₘₛ white noise+spurs@k×500 MHz, k∈ [symbol] . Ten exemplary cBG output sequences of 1 Mbit were considered in each test. The numbers in the brackets in the ‘TEST’ column denote the equivalent NIST tests. Tests that were passed are indicated by a check mark (“√”). Tests that were failed are indicated by an x mark (“ [symbol] ”).

TABLE I
Statistical Test Results of a Single Exemplary cBG cell in Different Test Cases of Supply Noise

| | WHITE NOISE | | 10 mvᵣₘₛ WHITE NOISE + SPURS @ | |
|---|---|---|---|---|
| TEST | 20 mvᵣₘₛ | 10 mvᵣₘₛ | k × 100 MHz, kϵ [symbol] | k × 500 MHz, kϵ [symbol] |
| Template Matching (7, 8) | ✓ | ✓ | ✓ | ✓ |
| Discrete Fourier Transform (6) | ✓ | ✓ | ✓ | ✓ |
| Linear Complexity (10) | ✓ | ✓ | ✓ | ✓ |
| Frequency of m-bit Patterns (11) | ✓ | ✓ | ✓ | ✓ |
| Random Excursions (14, 15) | ✓ | ✓ | ✓ | ✓ |
| Binary Matrix Rank (5) | ✓ | ✓ | ✓ | ✓ |
| Maurer's “Universal Statistical” (9) | ✓ | ✓ | [symbol] | [symbol] |
| Longest-Run-of-Ones in a Block (4) | ✓ | ✓ | [symbol] | [symbol] |
| Runs (3) | ✓ | [symbol] | [symbol] | [symbol] |
| Approximate Entropy (12) | ✓ | [symbol] | [symbol] | [symbol] |
| Cumulative Sums (13) | ✓ | [symbol] | [symbol] | [symbol] |
| Frequency (1) | ✓ | [symbol] | [symbol] | [symbol] |
| Frequency within a Block (2) | ✓ | [symbol] | [symbol] | [symbol] |

The first two columns show the statistical test results for an exemplary cBG cell with 20 mvᵣₘₛ and 10 mvᵣₘₛ white noise at the cBG power supply respectively. It is seen that the 20 mvᵣₘₛ white noise test case exhibits good statistical properties and that it passes all the tests. The 10 mvᵣₘₛ white noise test case passed most of the tests. The last two columns present statistical test results for an exemplary cBG cell with 10 mvᵣₘₛ white noise with additional spurs (and their multiples) at 100 MHz and 500 MHz respectively at the cBG power supply, both of which were 15 mvᵣₘₛ dominant spur magnitudes. In these cases the cell failed several tests.

However, the exemplary cBG cell successfully passed all the tests that are essential for immunity to power analysis, namely: Template Matching, Discrete Fourier Transform, Linear Complexity, Frequency of m-bit Patterns and Random Excursions.

### F. Statistical Tests at the System Level

The test-bench and power analysis attack process described in [2] were used to evaluate the security of the system level implementation. Module Under Test (MUT) 700 consists of two main blocks: combinatorial logic consisting of the 8-bit CMOS 5-box and an ADDKEY module (a nonlinear part of the AES algorithm [19]), both of which included embedded BG gates. MUT 700 also includes register arrays located at the input and output of the combinatorial logic. To examine the exemplary cBG based implementation, the RPC signals (the control signals of the BG gates) were generated by exemplary cBG cells.

Table II presents the SNR values obtained for the power analysis attacks on the BG based implementation, for a single key chosen as an example. The SNR was defined as the ratio between the maximum correlation value of the correct key and the maximal correlation among the wrong key values. If the SNR is greater than 1, the correct key may be extracted. Therefore the goal is to reduce the average SNR (over all possible keys) to 1 or less. For comparison, the column labeled “External TRNG” in Table II shows the results presented in [2] in which the RPC signals were generated by an external TRNG module.

The effectiveness of the exemplary cBG combinatorial logic was tested on all the keys and proved to be efficient. The SNR values for the exemplary cBG test case were measured for three types of supply noise with 10 mvᵣₘₛ white noise. Table II clearly shows that the use of exemplary cBG cells as the RPC signals of the BG gates kept the S-box immune to power analysis attacks (i.e. SNR was less than 1 in all test cases).

TABLE II
SNR vs. Number of Injected Input Vectors for BG Based Implementation

| | | SNR | | | | |
|---|---|---|---|---|---|---|
| | | | | cBG cells with 10 mvᵣₘₛ white noise | | |
| | | Without | External | | with Spurs @ | with Spurs @ |
| | | BG gates | TRNG | No Spurs | k × 100 MHz, kϵ [symbol] | k × 500 MHz, kϵ [symbol] |
| # of input vectors | 500 | ≥1.607 | 0.745 | 0.711 | 0.689 | 0.750 |
| | 1000 | | 0.805 | 0.693 | 0.710 | 0.780 |
| | 2000 | | 0.862 | 0.759 | 0.801 | 0.833 |
| | 5000 | | 0.873 | 0.786 | 0.856 | 0.917 |
| | 10000 | | 0.892 | 0.811 | 0.895 | 0.950 |

Changes in temperature or in power supply level do not significantly affect the outcome. Changing these parameters may affect the amplitude, DC level and the frequency of the VCO. However, changes in the VCO amplitude are not problematic since a logical ‘0’ or ‘1’ at the exemplary cBG cell is obtained in any case. If the DC level changes at the VCO output, a similar DC level change will occur at the DFF as well (reflecting its decision point) since they are both standard CMOS cells. The designer only has to ensure that there are a sufficiently large number of VCO oscillations within a DFF clock cycle so that the change in the VCO frequency will not impact the output sequence. The test case presented herein uses a 100 MHz clock, which is sufficient since the VCO oscillates at around 6 GHz.

### G. Area Overhead and Effective Throughput

Table III shows the high efficiency in terms of area overhead and effective throughput obtained when using exemplary cBG cells.

The area values of the exemplary cBG cell and the TRNG modules presented in [10], [11], [13], [15] and [16] are shown in Table III. For a fair comparison, these values were scaled to the values related to a 65 nm process. Two scaling calculations are shown: a scaling of 70% between consecutive processes as a common estimation for digital implementation, and a scaling of 90% as an estimation for analog implementations (which is more accurate scaling for the TRNGs, since they mostly consist of analog components).

As shown in Table III, the areas of all the TRNGs are many times larger than the area of the exemplary cBG cell. If the routing area saved by the use of exemplary cBG cells is also considered, additional area is saved. As another benefit, the exemplary cBG cells generate different sequences whereas each of the TRNGs produces one sequence.

It was found that in order to achieve the high immunity of an 8-bit S-box to power analysis attacks, approximately 100 BG gates should be embedded in the S-box (assuming the percentage of BG gates out of all gates in the S-box is around 20%), and should receive different sequences.

The power consumption (rms) of a single active exemplary cBG element (CLK1=0) is equivalent to 1.15 standard library-cell FFs (a positive edged-triggered, D-type FF) power consumption operating at CLK2=500 MHz.

The effective throughput of the sequence generator is defined as the number of bits generated per second normalized to a 1 mm² area. This parameter indicates the efficiency of the modules for the same number of different sequences. The throughput values of the TRNGs are 12.5 Mbps for [10], 10 Mbps for [13], 1.4 Mbps for [11], 2.4 Gbps for [15], and 50 Mbps for [16]. A throughput of 100 Mbps is considered for the exemplary cBG though it may still provide similar results for 400 MHz clock. As can be seen from Table III, the effective throughput of the exemplary cBG is about 30 times higher than the effective throughput of the TRNG presented in [15], and much higher than the other TRNGs.

TABLE III

| | | | TRNG | TRNG | TRNG | TRNG | TRNG |
|---|---|---|---|---|---|---|---|
| | | cBG | [10] | [13] | [11] | [15] | [16] |
| Process | | 65 | 40 | 180 | 2000 | 45 | 130 |
| Single cell area (mm²) | | 11.88E−6 | — | 16E−3 | 1.5 | 4E−3 | 145E−3 |
| Area factor related to | 70% | ×1 | ×2.64 | ×0.13 | ×1.05E−3 | ×2.08 | ×0.25 |
| 65 nm | 90% | ×1 | ×1.3 | ×0.53 | ×0.12 | ×1.23 | ×0.65 |
| Area scaled to 65 nm | 70% | 11.88E−6 | — | 2.08E−3 | 1.46E−3 | 8.34E−3 | 36.25E−3 |
| (mm²) | 90% | 11.88E−6 | — | 8.48E−3 | 0.18 | 4.92E−3 | 94.25E−3 |
| Normalization to cBG | 70% | 1 | — | 175 | 133 | 702 | 3051 |
| area | 90% | 1 | — | 713 | 15151 | 414 | 7933 |

| | | | | | | |
|---|---|---|---|---|---|---|
| Throughput (Mbps) | 100 | 12.5 | 10 | 1.4 | 2400 | 50 |
| $Effective Throughput \qquad ( \frac{\frac{bits}{sec}}{{mm}^{2}} )$ | 8.41E+12 | — | 4.8E+9 | 0.96E+9 | 0.28E+12 | 1.38E+9 |

The embodiments described herein present a compact bit generator which may easily be embedded within a logic circuit design due to its small size and low resource costs. The randomness of cBG output bit series is created by inherent properties of circuit operation, such as background noise and clock jitter. There is therefore no need for additional noise source circuitry which actively generates a random signal. The cBG may be formed from standard digital cells using a standard circuit design tool. Implementing multiple cBGs as an integral part of the logic circuit design makes it extremely difficult to neutralize them; i.e., makes a tampering attack infeasible.

The methods as described above are used in the fabrication of integrated circuit chips.

Aspects of the present invention are described herein with reference to flowchart illustrations and/or block diagrams of methods and apparatus (systems) according to embodiments of the invention. It will be understood that some blocks of the flowchart illustrations and/or block diagrams, and some combinations of blocks in the flowchart illustrations and/or block diagrams, may be implemented at least in part by computer readable program instructions.

The flowchart and block diagrams in the Figures illustrate the architecture, functionality, and operation of possible implementations of systems and methods according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is expected that during the life of a patent maturing from this application many relevant voltage controlled oscillators, samplers, inverters, flip-flops, logic circuits, circuit design tools, cell libraries and logic circuit technologies will be developed and the scope of the term oscillator, sampler, inverter, flip-flop, logic circuit, circuit design tool, cell library and logic circuit technology is intended to include all such new technologies a priori.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A bit generator comprising:
a voltage controlled oscillator (VCO) powered by a supply voltage; and
a sampler associated with said VCO, configured to output a non-deterministic bit series generated by sampling an output of said VCO, wherein a randomness of said non-deterministic bit series depends on at least one of: inherent background noise and inherent clock jitter.

2. A bit generator according to claim 1, wherein said bit generator does not comprise noise source circuitry configured to generate a random signal.

3. A bit generator according to claim 1, further comprising an enable input adapted to input an enable signal for enabling and disabling said VCO.

4. A bit generator according to claim 1, wherein an output of said bit generator is connected to an input of a digital element.

5. A bit generator according to claim 4, wherein said digital element is powered by said supply voltage.

6. A bit generator according to claim 1, wherein said bit generator is embedded in a logic circuit.

7. A bit generator according to claim 1, wherein a sampling rate of said sampler is smaller than an oscillation frequency of said VCO.

8. A bit generator according to claim 1, wherein said VCO comprises a plurality of logic gates interconnected so as to create an oscillator.

9. A bit generator according to claim 1, wherein said VCO comprises a ring oscillator.

10. A bit generator according to claim 1, wherein said VCO comprises at least one standard digital cell.

11. A bit generator according to claim 1, wherein said VCO comprises inverters connected in a ring.

12. A bit generator according to claim 1, wherein said VCO comprises an exclusive OR (XOR) gate connected to an inverter in a ring, said inverter output being connected to an input of said XOR gate and to an input of said sampler.

13. A bit generator according to claim 12, wherein a second input of said XOR gate is connected to an enable signal, wherein inputting a first logic level into said second input enables operation of said VCO and inputting a second logic level into said second input disables operation of said VCO.

14. A bit generator according to claim 1, wherein said sampler is configured to sample said output of said VCO in accordance with a clock signal.

15. A bit generator according to claim 14, wherein said sampler comprises a Flip-Flop (FF) having a first input connected to an output of said VCO and a second input connected to said clock signal.

16. A logic circuit comprising:
a plurality of bit generators configured to output respective non-deterministic bit series, wherein a respective randomness of each of said non-deterministic bit series depends on at least one of: inherent background noise for said respective bit generator and inherent clock jitter for said respective bit generators; and
a plurality of logic gates, each of said logic gates comprising:
a random signal input configured to input a non-deterministic bit series from a respective one of said bit generators; and
at least one logic input configured to input respective logic signals,
wherein said logic gate is configured to implement a respective logic operation on said non-deterministic bit series input from said respective one of said bit generators and said respective logic signals.

17. A logic circuit according to claim 16, wherein at least one of said bit generators does not comprise noise source circuitry configured to produce random electrical noise.

18. A logic circuit according to claim 16, wherein at least one of said bit generators comprises a respective enable input adapted to input an enable signal for enabling and disabling said respective bit generator.

19. A logic circuit according to claim 16, wherein at least two of said bit generators output uncorrelated non-deterministic bit series.

20. A logic circuit according to claim 16, wherein at least two of said bit generators are powered by different supply voltages.

21. A logic circuit according to claim 16, wherein each of said bit generators comprises:
a respective voltage controlled oscillator (VCO); and
a respective sampler associated with said VCO, configured to generate said respective non-deterministic bit series by sampling an output of said respective VCO.

22. A logic circuit according to claim 21, wherein, for at least one of said bit generators, a sampling rate of said respective sampler is smaller than an oscillation frequency of said respective VCO.

23. A logic circuit according to claim 21, wherein, for at least one of said bit generators, said respective VCO comprises a plurality of logic gates interconnected so as to create an oscillator.

24. A logic circuit according to claim 21, wherein, for at least one of said bit generators, said respective VCO comprises a ring oscillator.

25. A logic circuit according to claim 21, wherein, for at least one of said bit generators, said respective VCO comprises an exclusive OR (XOR) gate connected to an inverter in a ring, said inverter output being connected to an input of said XOR gate and to an input of said sampler, and wherein a second input of said XOR gate is connected to an enable signal for enabling and disabling said VCO.

26. A logic circuit according to claim 21, wherein, for at least one of said bit generators, said respective sampler is configured to sample said output of said VCO in accordance with a clock signal.

27. A logic circuit according to claim 26, wherein said respective sampler comprises a Flip-Flop (FF) having a first input connected to an output of said VCO and a second input connected to said clock signal.

28. A logic circuit according to claim 26, wherein at least one of said logic gates comprises a blurring gate.
